(19) United States
(12) Patent Application Publication
(10) Pub. No.: US 2019/0259676 A1
(43) Pub. Date: Aug. 22, 2019

(54) III-V CHIP-SCALE SMT PACKAGE

(71) Applicant: BAE SYSTEMS Information and Electronic Systems Integration Inc., Nashua, NH (US)

(72) Inventor: Timothy M. DRESSER, Wilton, NH (US)

(21) Appl. No.: 15/900,838

(22) Filed: Feb. 21, 2018

(51) Int. Cl. H01L 23/10; H01L 23/552; H01L 23/055; H01L 23/498; H01L 21/48

(52) U.S. Cl. CPC H01L 23/10; H01L 23/552; H01L 21/4803; H01L 23/49816; H01L 21/4817; H01L 23/055

(57) ABSTRACT

The system and method for a chip-scale surface-mount technology (SMT) packaging method for semiconductor devices. The chip-scale SMT package uses an air-cavity lid to protect the active face of a MMIC, or other device either active or passive, from the environment. In some examples, the cover provides electrical routing. In some examples, the cover also provides electromagnetic shielding. In some cases, the Au semiconductor devices bond pads which are converted to a Pb/Sn compatible metal.

### FIELD OF THE DISCLOSURE

The present disclosure relates to protective packaging for electronic devices and more particularly to chip-scale surface-mount technology packages.

### BACKGROUND OF THE DISCLOSURE

It has been recognized that high frequency active circuits require special consideration when packaging. Typically, that is in the form of hermetic sealing, which also has drawbacks such as it is challenging to retain electrical performance while providing sufficient environmental protection and low thermal resistance (e.g., junction to package and junction to ambient). For non-hermetic options which are used on bare die, chip and wire in metal multi-chip module (MCM), and plastic quad-flat no-lead (QFN) packages they require thick on die passivation, which also limits high frequency performance.

Wherefore it is an object of the present disclosure to overcome the above-mentioned shortcomings and drawbacks associated with the conventional hermetic and non-hermetic sealing techniques for electronic devices.

### SUMMARY OF THE DISCLOSURE

One aspect of the present disclosure is a method of making a chip-scale surface mount technology package, comprising: providing a device; providing a cover with an integral air cavity; bonding the cover to the device via a bonding agent to form a hermetic or near hermetic bond; providing one or more external interconnects in the cover; filling the one or more external interconnects in the cover with solid metal; and adding one or more final surface metals to the cover to form a chip scale surface mount technology package.

One embodiment of the method of making a chip-scale surface mount technology package is wherein the air cavity is etched into the cover. In some cases, the one or more final surface metals comprise selective AuSn.

Another embodiment of the method of making a chip-scale surface mount technology package is wherein the cover comprises glass. In certain embodiments, the device is active.

Yet another embodiment of the method of making a chip scale surface mount technology package is wherein the step of attaching the cover to an active device further comprises the steps of: placing the cover onto a monolithic microwave integrated circuit; aligning the cover onto the monolithic microwave integrated circuit; and reflowing the final surface metal. In some cases, the aligning the cover step utilizes fiducials in the cover and the monolithic microwave integrated circuit. In certain cases, the method of making a chip scale surface mount technology package further comprises placing Pb/Sn solder balls and reflowing the Pb/Sn solder balls as the bonding agent. In some cases, the method of making a chip scale surface mount technology package further comprises attaching the cover to the monolithic microwave integrated circuit using thermal compression bonding or epoxy as the bonding agent.

Yet still another embodiment of the method of making a chip scale surface mount technology package is wherein the cover can be attached wafer to wafer, cover to wafer, or cover to individual monolithic microwave integrated circuit. In some cases, the method of making a chip scale surface mount technology package further comprises dicing a wafer.

Another aspect of the present disclosure is a chip-scale surface mount technology package, comprising: a device; and a cover attached to a top of the device via a bonding agent, wherein the cover provides an air cavity and provides environmental protection to the device via a hermetic bond.

In one embodiment of the chip-scale surface mount technology package the cover provides electrical routing. In some cases, the cover provides electrical shielding. In certain cases, the device is active.

In another embodiment of the chip-scale surface mount technology package the cover adapts a gold interface on a monolithic microwave integrated circuit to a solder interface on a circuit board.

Yet another aspect of the present disclosure is a chip-scale surface mount technology package, comprising: a device; and a cover attached to a bottom of the device via a bonding agent, wherein the cover provides an air cavity and provides environmental protection to the device via a hermetic bond.

One embodiment of the chip-scale surface mount technology package is wherein the cover provides electrical routing. In some cases, the device is active.

Another embodiment of the chip-scale surface mount technology package is wherein the cover adapts a gold interface on a monolithic microwave integrated circuit to a solder interface on a circuit board.

These aspects of the disclosure are not meant to be exclusive and other features, aspects, and advantages of the present disclosure will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the disclosure will be apparent from the following description of particular embodiments of the disclosure, as illustrated in the accompanying drawings in which like reference characters refer to the same parts throughout the different views. The drawings are not necessarily to scale, emphasis instead being placed upon illustrating the principles of the disclosure.

FIG. 1 shows an embodiment of the present disclosure with a Monolithic Microwave Integrated Circuit (MMIC) that is on the bottom, is unshielded, and the external interconnect is thru the MMIC substrate.

FIG. 2 shows an embodiment of the present disclosure with a Monolithic Microwave Integrated Circuit (MMIC) that is on the bottom, is shielded, and the external interconnect is thru the MIMIC substrate.

FIG. 3 shows an embodiment of the present disclosure with a Monolithic Microwave Integrated Circuit (MMIC) that is on the top, is shielded, and the external interconnect is thru the cover.

FIG. 4 shows an embodiment of the present disclosure with a Monolithic Microwave Integrated Circuit (MMIC) that is on the top, is unshielded, and the external interconnect is thru the cover.

FIG. 5 shows the device portion of one embodiment of the system of the present disclosure which includes one or more interconnect layers.

FIG. 6A, FIG. 6B, and FIG. 6C shows a bottom view, a first cross sectional side view and a flipped cross sectional side view, respectively, of the cover or lid portion of one embodiment of the present disclosure with an air cavity, metal pads for external interconnect, and a sealing ring.

FIG. 7A shows the device portion of one embodiment of the system of the present disclosure as seen in FIG. 5.

FIG. 7B shows the cover or lid portion of one embodiment of the system of the present disclosure as seen in FIG. 6A.

FIG. 7C shows the device portion and the cover or lid portion as combined, as in the embodiment shown in FIG. 4.

FIG. 8 shows yet another embodiment of the system of the present disclosure with a Monolithic Microwave Integrated Circuit (MMIC) that is on the bottom, is shielded, and the external interconnect is thru the MMIC substrate.

FIG. 9 shows a flowchart of one embodiment of the method of the present disclosure.

### DETAILED DESCRIPTION OF THE DISCLOSURE

One embodiment of the present disclosure is a chip-scale surface-mount technology (SMT) packaging method for III-V semiconductor devices. In some cases, this provides for low cost SMT packaging of III-V Monolithic Microwave Integrated Circuit (MMICs). In some cases, the low cost SMT packaging is useful for active and/or passive devices.

Certain embodiments of the present disclosure provide a chip-scale SMT package that uses an air-cavity lid to protect the active face of the MMIC, or other device, from the environment. In some embodiments, the Au MIMIC bondpads are converted to a Pb/Sn compatible metal interface. Copper, nickel, tin and their alloys are often used with electronic solders (Pb/Sn and Pb free Sn solders). In certain embodiments, the lid is glass. Other versions of this lid could be, but are not limited to polymers, ceramics, and metals. Certain features of these lids include providing sufficient hermeticity, compatible coefficient of thermal expansion (CTE) properties and some form of thru substrate via interconnect thru lid for certain applications. In some cases, the lid is also transparent or translucent.

One benefit of the packaging of the present disclosure is enabling low-cost chip-scale SMT packaging of GaAs and GaN components that would otherwise need to be in a hermetic or near-hermetic housing (e.g., metal and/or ceramic) that encompasses the entire device. In many applications there is a challenge to combine the performance of bare MMICs with the low cost of surface mount circuit boards. At higher frequencies (e.g., above 10 GHz) MMICs require air above the surface of the device (especially the gate of field effect transistors). Traditional plastic overmolded packaging cannot provide these air cavities. Even low-dielectric constant die coating is typically not enough. Hermetic metal and ceramic packages have traditionally provided these air cavities, but with higher procurement cost as well as significantly larger footprint. Some examples of plastic air-cavity packages exist, but few of these options qualify as chip-scale packaging and operate thru 40 GHz and beyond.

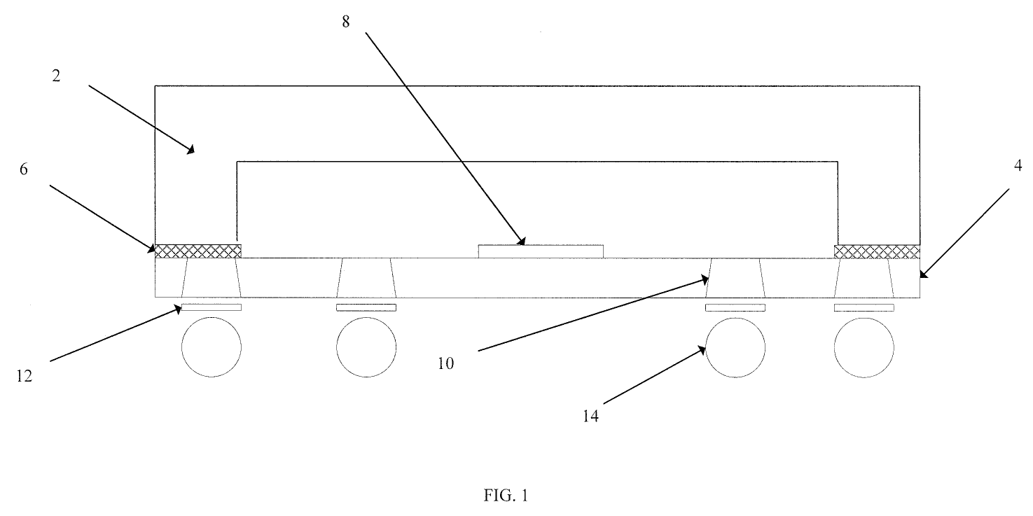

Referring to FIG. 1, an embodiment of the present disclosure with a Monolithic Microwave Integrated Circuit (MMIC) that is on the bottom, is unshielded, and where the external interconnect is thru the MIMIC substrate is shown. More specifically, the chip-scale packaged MMIC can have a ball grid array (BGA) interface. A BGA is a type of surface-mount packaging (a chip carrier) used for integrated circuits. BGA packages are used to permanently mount devices such as microprocessors. A BGA can provide more interconnection pins than can be put on a dual in-line or flat package. The whole bottom surface of the device can be used, instead of just the perimeter. The leads are also on average shorter than with a perimeter-only type, leading, to better performance at high speeds. In some cases, perimeter-only, or other methods may be used or even preferred depending on the application. Soldering of BGA devices requires precise control and is usually done by automated processes.

In this embodiment, the MIMIC is on the bottom and the cover, or lid, only provides environmental protection. In some embodiments, the MIMIC must have backside metallization that is compatible with Sn/Pb solder. In some cases, there is no electromagnetic shielding.

Still referring to FIG. 1, the MIMIC substrate 4, has one or more thru substrate vias (TSV) 10, and a barrier metal (aka under bump metal) 12. In some cases, there are one or more solder balls 14. In certain embodiments, a hermetic seal ring 6 is used to attach the lid 2. The active surface of the MIMIC 8 is shown within an air cavity formed by the lid 2 and the MIMIC 8 is coupled to a bottom surface of the MIMIC substrate 4.

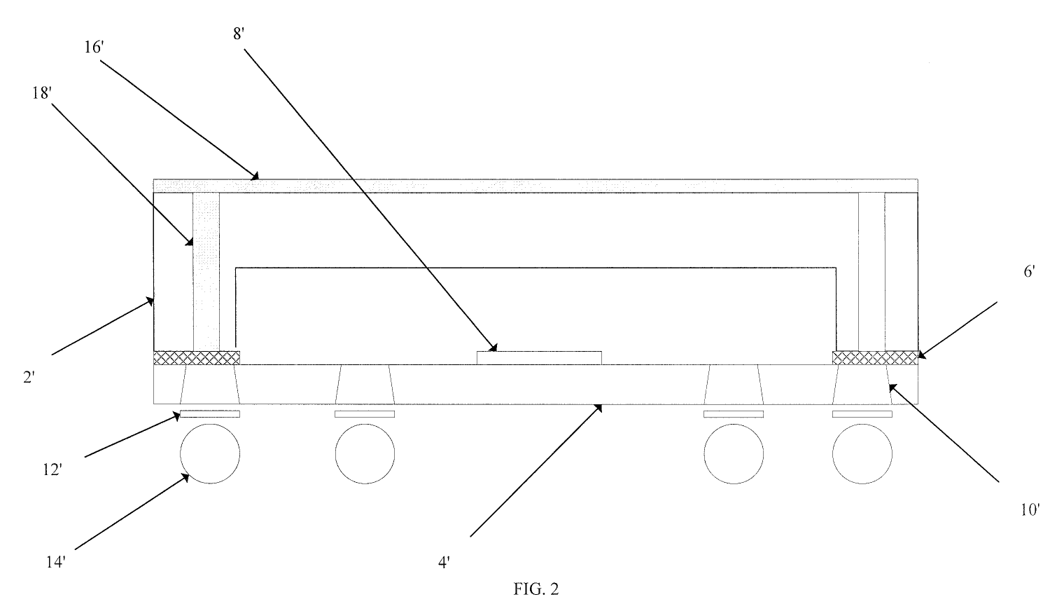

Referring to FIG. 2, an embodiment of the present disclosure with a Monolithic Microwave Integrated Circuit (MIMIC) that is on the bottom, is shielded, and where the external interconnect is thru the MMIC substrate is shown. More specifically, the chip-scale packaged MMIC of this embodiment has a ball grid array (BGA) interface. In this embodiment, the MMIC 8′ is on the bottom and the cover, or lid 2′, provides environmental protection and electromagnetic shielding 16′. Once again the MMIC must have backside metallization that is compatible with Sn/Pb solder. In some embodiments, special considerations need to be made when screening MMICs on wafer for the MMIC down configurations; a non-conductive platen is required so as to not short out the thru substrate MIMIC vias 10′. The MIMIC substrate 4, has one or more thru substrate vias (TSV) 10′, and barrier metal (aka under bump metal) 12′. In some cases, there are one or more solder balls 14′. In some cases a hermetic seal ring 6′ is used to attach the lid 2′. The active surface of the MMIC 8′ is shown within an air cavity formed by the lid 2′. This embodiment has electromagnetic shielding 16′ on the lid which is connected to the MMIC with through substrate vias 18′ in the lid.

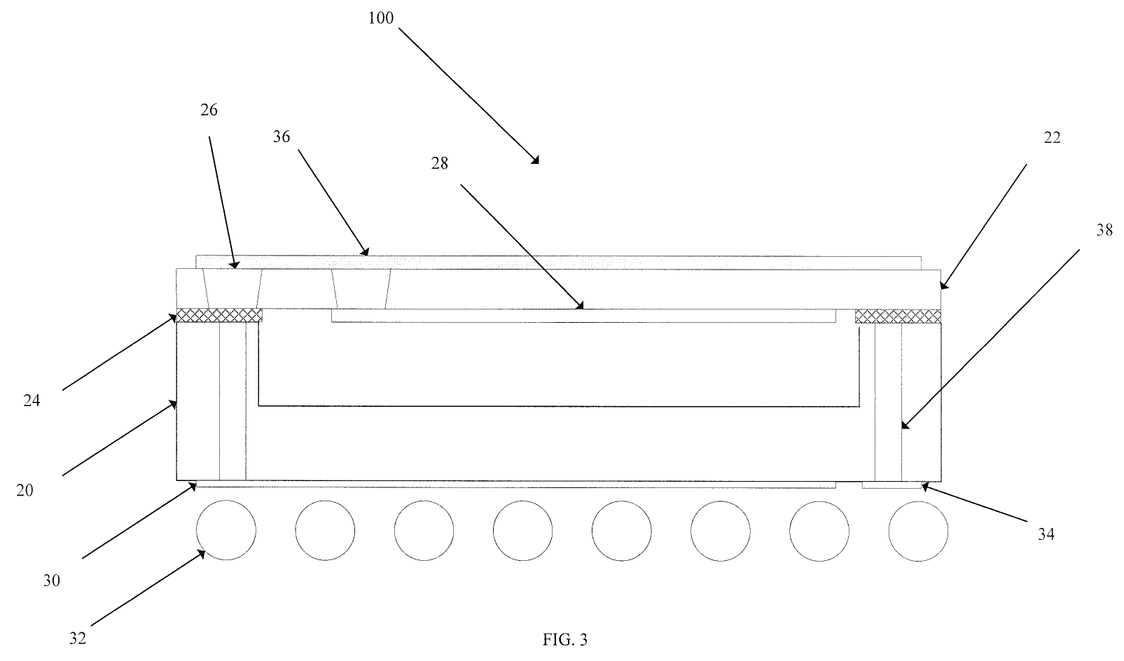

Referring to FIG. 3, an embodiment of the present disclosure with a Monolithic Microwave Integrated Circuit (MMIC) that is on the top, is shielded, and where the external interconnect is thru the cover is shown. More specifically, the chip-scale packaged MIMIC in this embodiment has a ball grid array (BGA) interface. In certain cases, this method of attaching covers, or lids, only increases the size of the die by a few hundred microns, versus a few millimeters with ceramic and metal packages. In some embodiments, the inductance of wire bonds is traded for thru substrate vias. In some cases, a hermetic seal ring 24 is used to attach the lid 20. The active surface of the MIMIC 28 is shown within an air cavity formed by the lid 20 to the device (here a MIMIC). This embodiment has electromagnetic shielding 26, which is connected to the MIMIC with through substrate vias 26. In some embodiments, special considerations need to be made when screening MMICs on wafer for the MMIC down configurations; a non-conductive platen is required so as to not short out the thru substrate MMIC vias 26. The MIMIC substrate 22, has one or more thru substrate vias 26, and the barrier metal (aka under bump metal) 30, 34 is shown on the lid. This is interconnected via a through substrate via 38 in the lid. In some cases, solder balls 32 are added to the lid.

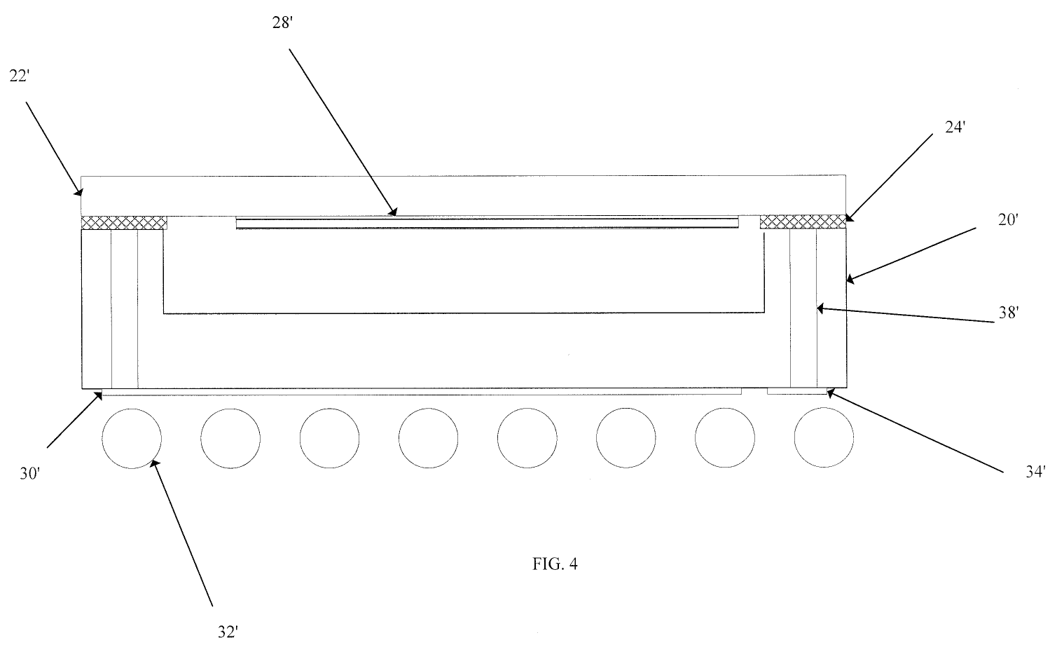

Referring to FIG. 4, an embodiment of the present disclosure with a Monolithic Microwave Integrated Circuit (MMIC) that is on the top, is unshielded, and where the external interconnect is thru the cover is shown. More specifically, in some cases a hermetic seal ring 24′ is used to attach the lid 20′ to the MIMIC substrate 22′. The active surface of the MIMIC 28′ is shown within an air cavity formed by the lid 20′. It is understood that the MIMIC may be, in certain cases, multilayered. In certain embodiments, barrier metal (aka under bump metal) 30′, 34′ is shown on the lid and this is interconnected via a through substrate via 38′ in the lid. In some cases, solder balls 32′ are added to the lid. In certain embodiments, there is a lack of TSVs in the MMIC substrate.

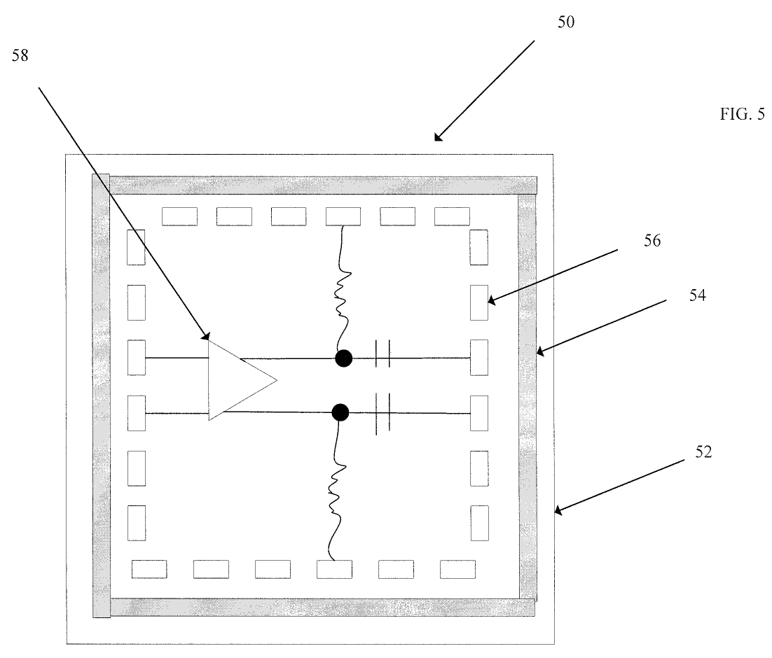

Referring to FIG. 5, the device portion of one embodiment of the system of the present disclosure which includes one or more interconnect layers is shown. More particularly, a GaN or GaAs MIMIC is shown 50 where the active face 58 comprises a plurality of signal pads 56 and a seal ring 54 on a substrate 52.

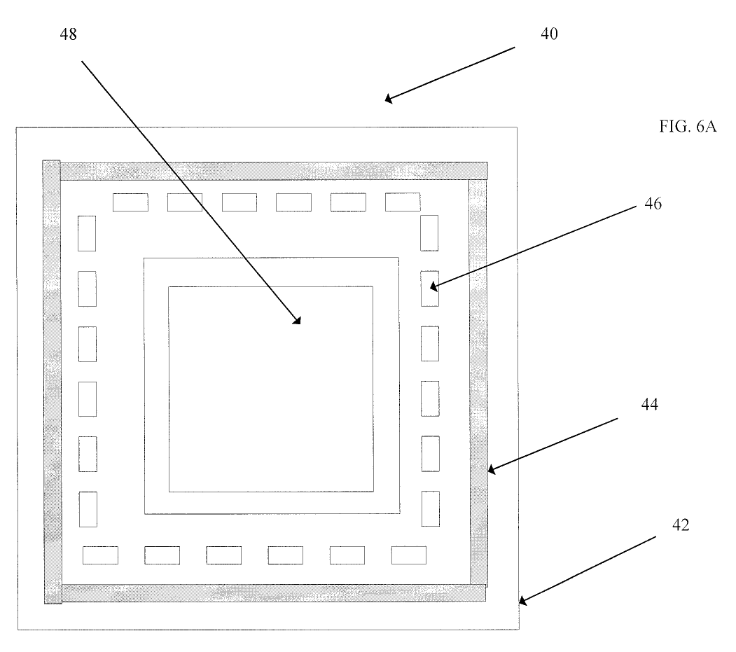

Referring to FIG. 6A, FIG. 6B, and FIG. 6C a bottom view, a first cross sectional side view and a flipped cross sectional side view, respectively, of the cover or lid portion 40 of one embodiment of the present disclosure is shown with an air cavity 48, metal pads for external interconnect 46 with thru substrate vias 47, and a sealing ring 44 on a substrate 42. More particularly, an air cavity 48 is shown along with a plurality of signal pads 46 and a seal ring 44. In certain embodiments, the lid 40 is made of glass and there are metal pads 49 for interconnectivity on the outer surface of the lid.

In certain embodiments of the present disclosure, the air-cavity lid, or cover, as shown in FIG. 6A-FIG. 6C protects the active face of the MMIC as shown, for example, in FIG. 5 from environmental effects. In some cases, the Au MIMIC bondpads are converted to a Pb/Sn compatible metal. In some cases, the lid is metalized on both sides 46, 49 and includes filled metal vias 47.

The MMIC facing side of the lid can be pre-coated with AuSn solder in certain embodiments. In one embodiment, a narrow seal ring is added at the outer edge of the MMIC. Inside of the seal ring includes the signal and power bondpads. When the lid is soldered to the MMIC the seal ring and bondpads are connected between the MMIC and the lid. In some cases, the lids, or covers, can be attached individually—each lid to each individual die, individual lid to wafer, or wafer to wafer. In some embodiments, prior to attaching the lid, the MMIC can be screened using traditional probes and probe stations.

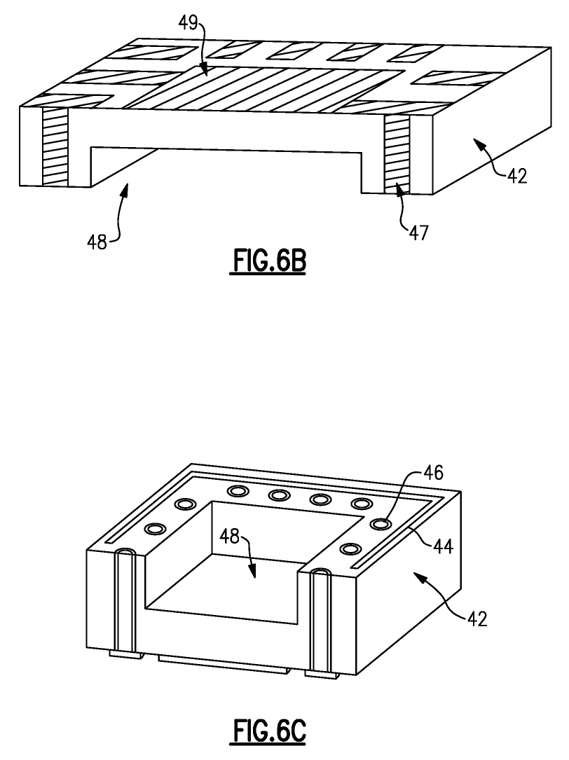

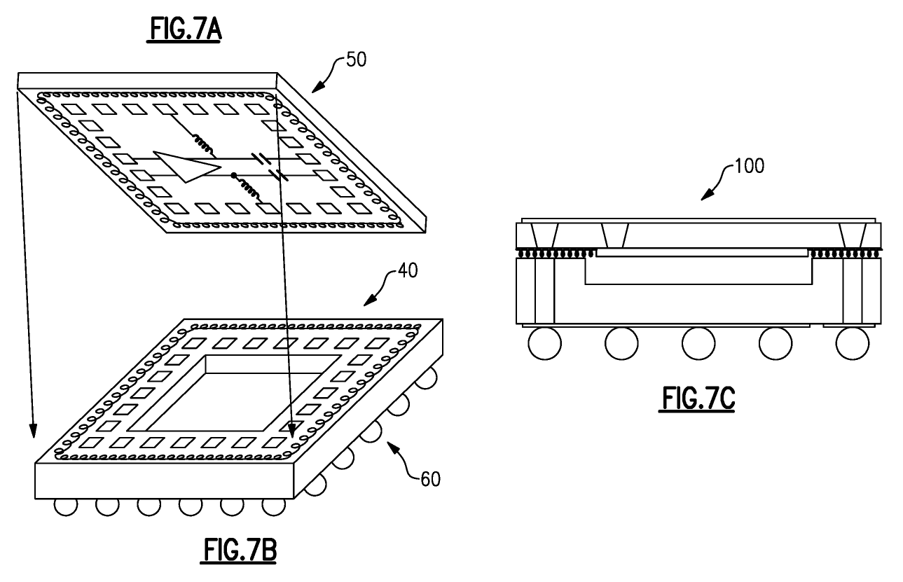

Referring to FIG. 7A, the device portion of one embodiment of the system of the present disclosure as seen in FIG. 5 is shown. More specifically, a GaN or GaAs MMIC is shown 50 prior to assembly with a cover. Referring to FIG. 7B, the cover portion of one embodiment of the system of the present disclosure as seen in FIG. 6 is shown. More specifically, a cover or lid 40 providing an air cavity is shown prior to assembly with a MMIC or the like. Referring to FIG. 7C, the device portion and the cover portion once combined, as in the embodiment seen in FIG. 4 is shown.

In certain embodiments, the cover provides environmental protection, electromagnetic shielding, and electrical interconnect into the circuit card. The MMIC is fundamentally the same as what are typically used, except for the addition of a seal-ring that surrounds the bond pads in some embodiments. The bond pads are near the component outline to facilitate wafer prove screening/electrical test. Any thru substrate vias in the MMIC must be sufficiently sealed on the backside. The existing backside Au metal may be a sufficient barrier (hermetic or near hermetic) in certain embodiments.

Fine and gross leak testing is used to determine the effectiveness of package seals in microelectronic packages. Damaged or defective seals and feedthroughs allow ambient air/water vapor to enter the internal cavity of the device which can result in internal corrosion leading to device failures. Hermeticity testing may be performed just after the sealing process, or during screening/qualification. Hermeticity testing can be performed in accordance with MIL-STD-883, Test Method 1014 for hybrids/microcircuits and MIL-STD-750 for 1071 for discrete semiconductor devices. For MIL-STD-883H, Test Method 1014.13 categorizes a “seal” and provides for equivalent standard leak rates (atm cc/s air) for volumes: 1) ≤0.01 cc: 5×10⁻⁸; 2) >0.01 and <0.5 cc: 1×10⁻⁷; and 3) ≥0.5 cc: 1×10⁻⁶. For MIL-STD-750E, Test Method 1071.9 categorizes a “hermetic seal” for equivalent standard leak rates (atm cc/s air) for volumes: 1)≤0.002 cc: 5×10⁻¹⁰; 2) >0.002 and ≤0.05 cc: 1×10⁻⁹; 3) >0.02 and ≤0.5 cc: 5×10⁻⁹; and 4) ≥0.5 cc: 1×10⁻⁸.

It is understood that testing evaluates “exchange rates” or the amount of time it takes for a device to “ingest” some percentage of the atmosphere to which it is exposed. In some cases, a 50% exchange rate may be used. In some cases a 90% exchange rate may be used. In certain embodiments, the rate may be hours, days, or even years depending on the application. As used herein, “near-hermetic” means molecules of water or H₂S and the like may be blocked, but smaller diameter dry gases, e.g., hydrogen, helium, etc.; may be permitted to pass through the “seal.”

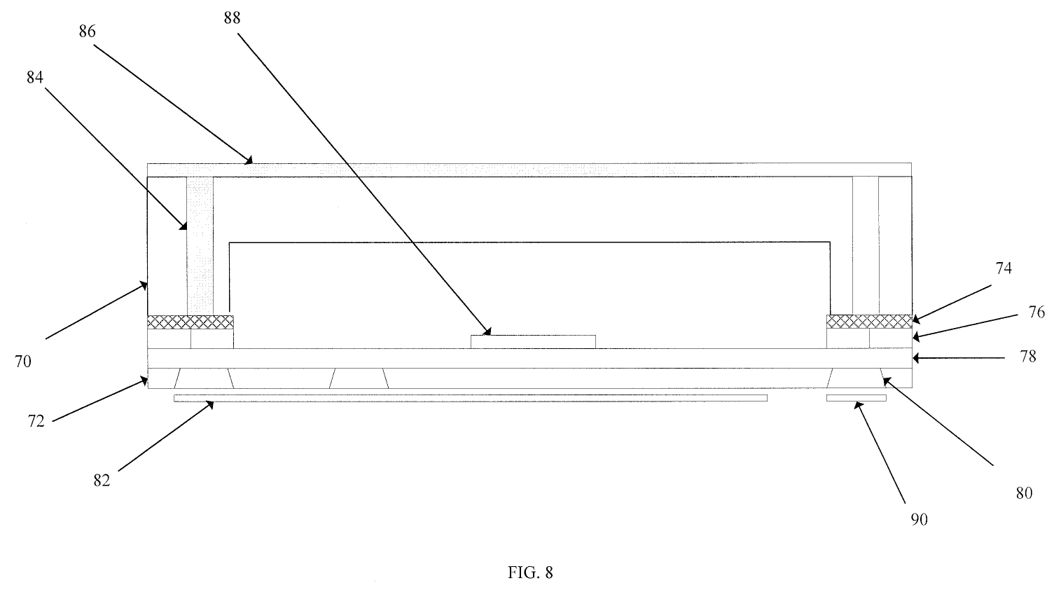

Referring to FIG. 8, yet another embodiment of the present disclosure is shown. More particularly, the Monolithic Microwave Integrated Circuit (MIMIC) that is on the bottom, is shielded, and the external interconnect is thru the MMIC substrate. The MIMIC substrate 78, 72, has one or more thru substrate vias (TSV) 80, and barrier metal (aka under bump metal) 82, 90. In some cases a hermetic seal ring 74 is used to attach the lid 70. In some cases, additional metallization 76 is present on the top layer 78 of the MIMIC substrate, where the substrate is multilayered. The active surface of the MMIC 88 is shown within an air cavity formed by the lid 70. This embodiment has electromagnetic shielding 86 on the lid which is connected to the MIMIC with through substrate vias 84 in the lid.

In some cases, the “lid” is an etched glass cover and the front side of the cover corresponds the face of the MMIC. The air cavity clears all active circuitry and the signal pads, power pads, and seal ring have AuSn solder pre-applied. In some cases, the cover contains thru substrate vias that provide electrical connections from the MIMIC to the circuit card. In some cases, the covers can be fabricated as six inch wafers, enabling wafer level packaging of MMICs.

In some cases, the circuit card side of the cover is a ball grid array (BGA) interface. It could also be a land grid array (LGA) or a quad-flat no-lead (QFN) compatible footprint. A land grid array (LGA) is a type of surface-mount packaging for integrated circuits (ICs) that is notable for having the pins on the socket (when a socket is used) rather than the integrated circuit. An LGA can be electrically connected to a printed circuit board (PCB) either by the use of a socket or by soldering directly to the board. Flat no-leads packages such as quad-flat no-leads (QFN) and dual-flat no-leads (DFN) physically and electrically connect integrated circuits to printed circuit boards. Flat no-leads, also known as micro leadframe (MLF) and SON (small-outline no leads), is a surface-mount technology. Flat no-lead is a near chip-scale plastic encapsulated package made with a planar copper lead frame substrate. Flat no-lead packages include an exposed thermal pad to improve heat transfer out of the integrated circuit (into the PCB). Heat transfer can be further facilitated by metal vias in the thermal pad. The QFN package is similar to the quad-flat package, and a ball grid array.

The key driving features for the present disclosure are as follows: 1) the package does not degrade electrical performance of the MMIC, or other device; 2) the package is not significantly larger than the active circuitry; 3) the package is compatible with standard Sn/Pb SMT processing and equipment, and as such no new process development was needed for the GaAs and GaN MMICs wafer fab; and 4) it is possible to screen MMICs on wafer prior to lid attachments, which in some embodiments allows for laser trim, etc. Lastly, these improvements come with a reduction in cost for the system.

One embodiment of the method of manufacturing the package of the present disclosure has the following steps. For cover fabrication, a through substrate via (TSV) or through-chip via is etched. A TSV is a vertical electrical connection (via) that passes completely through a substrate, e.g., a silicon wafer or die. TSVs are a high performance interconnect technique used as an alternative to wire-bond and flip chips to create 3D packages and 3D integrated circuits. Once the TSV is etched it is filled with conductive material, e.g., metal. Next the outer metal is patterned, followed by etching the air cavity. Then, any final surface metals are added. In some cases, selective AuSn is added.

One embodiment of the method of manufacturing the package of the present disclosure has the following steps. For MIMIC Fabrication, the wafer is fabricated using standard processing and is followed by a wafer test/electrical screen. For cover attachment, the cover is placed onto the MMIC wafer and fiducials in the lid are aligned with fiducials on the MMIC wafer. A fiducial is an object placed in the field of view of an imaging system which appears in the image produced, for use as a point of reference or a measure. It may be either something placed into or on the imaging subject, or a mark or set of marks in the reticle of an optical instrument. In some cases, the lid is clear where metal is pulled back. Next, the AuSn on the lid is reflowed. In some cases, Pb/Sn solder balls are placed and reflowed. Then, the wafer is diced and placed into waffle pack or tape and reel. In some cases, the bonding agent used to join the cover with the device can be, but is not limited to solder, polymer fusion, intermetallic bonding, and epoxy.

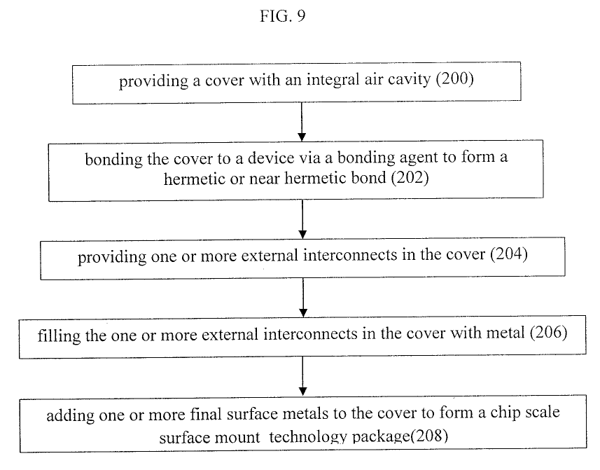

Referring to FIG. 9, a flowchart of one embodiment of the method of the present disclosure is shown. More specifically, the method of making a chip scale surface mount technology package begins with providing a cover with an integral air cavity (200). Then, bonding the cover to a device via a bonding agent to form a hermetic or near hermetic bond (202). Providing one or more external interconnects in the cover (204) and filling the one or more external interconnects in the cover with metal (206). Next, adding one or more final surface metals to the cover to form a chip scale surface mount technology package (208).

While various embodiments of the present invention have been described in detail, it is apparent that various modifications and alterations of those embodiments will occur to and be readily apparent to those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof herein, is meant to encompass the items listed thereafter and equivalents thereof as well as additional items while only the terms “consisting of” and “consisting only of” are to be construed in a limitative sense.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure.

1. A method of making a chip-scale surface mount technology package, comprising:
providing a high frequency device, wherein high frequency is above 10 Hz;
providing a cover with an integral air cavity for providing air above the surface of the device, wherein the integral air cavity is etched into the cover;
bonding the cover with the integral air cavity to the high frequency device via a bonding agent to form a hermetic or near hermetic bond;
providing one or more external interconnects in the cover with the integral air cavity;
filling the one or more external interconnects in the cover with the integral air cavity with metal; and
adding one or more final surface metals to the cover with the integral air cavity to form a chip scale surface mount technology package.

2. (canceled)

3. The method of making a chip-scale surface mount technology package according to claim 1, wherein the one or more final surface metals comprises selective AuSn.

4. The method of making a chip-scale surface mount technology package according to claim 1, wherein the cover comprises glass.

5. The method of making a chip-scale surface mount technology package according to claim 1, wherein the device is active.

6. The method of making a chip scale surface mount technology package according to claim 1, wherein the step of attaching the cover to the device further comprises the steps of:
placing the cover onto a monolithic microwave integrated circuit;
aligning the cover onto the monolithic microwave integrated circuit; and
reflowing the final surface metal.

7. The method of making a chip scale surface mount technology package according to claim 6, wherein the aligning the cover utilizes fiducials in the cover and the monolithic microwave integrated circuit.

8. The method of making a chip scale surface mount technology package according to claim 1, further comprising placing Pb/Sn solder balls and reflowing the Pb/Sn solder balls as the bonding agent.

9. The method of making a chip scale surface mount technology package according to claim 6, further comprising attaching the cover to the monolithic microwave integrated circuit using thermal compression bonding or epoxy as the bonding agent.

10. The method of making a chip scale surface mount technology package according to claim 6, wherein the cover can be attached wafer to wafer, cover to wafer, or cover to individual monolithic microwave integrated circuit.

11. The method of making a chip scale surface mount technology package according to claim 10, further comprising dicing a wafer.

12. A chip-scale surface mount technology package, comprising:
a high frequency device, wherein high frequency is above 10 GHz; and
a cover attached to a top of the device via a bonding agent, wherein the cover provides an integral air cavity for providing air above the surface of the device, provides electrical shielding, and provides environmental protection to the high frequency device via a hermetic bond, wherein the integral air cavity is etched into the cover.

13. The chip-scale surface mount technology package according to claim 12, wherein the cover with the integral air cavity provides electrical routing.

14. The chip-scale surface mount technology package according to claim 12, wherein the device is active and operates above 40 GHz.

15. The chip-scale surface mount technology package according to claim 12, wherein the cover with the integral air cavity adapts a gold interface on a monolithic microwave integrated circuit to a solder interface on a circuit board.

16. A chip-scale surface mount technology package, comprising:
a high frequency device, wherein high frequency is above 10 GHz; and
a cover attached to a bottom of the high frequency device via a bonding agent, wherein the cover provides an integral air cavity for providing air above the surface of the device, electrical routing, and provides environmental protection to the device via a hermetic bond, wherein the integral air cavity is etched into the cover.

17. The chip-scale surface mount technology package according to claim 16, wherein the device is active and operates above 40 GHz.

18. The chip-scale surface mount technology package according to claim 16, wherein the cover with the integral air cavity provides electrical shielding.

19. The chip-scale surface mount technology package according to claim 16, wherein the cover with the integral air cavity adapts a gold interface on a monolithic microwave integrated circuit to a solder interface on a circuit board.

20. The method of making a chip scale surface mount technology package according to claim 1, wherein the device is active and operates above 40 GHz.
